(19) United States
(12) Patent Application Publication
(10) Pub. No.: US 2013/0221212 A1
(43) Pub. Date: Aug. 29, 2013

(54) Coding Members With Embedded Metal Layers For Encoders

(71) Applicant: Yik Foong Soo, Penang (MY)

(72) Inventor: Yik Foong Soo, Penang (MY)

(73) Assignee: Avago Technologies ECBU IP (Singapore) Pte. Ltd., Singapore (SG)

(21) Appl. No.: 13/405,005

(22) Filed: Feb. 24, 2012

(51) Int. Cl. G01D 5/347; G01B 7/14; B32B 3/08; G01R 27/26

(52) U.S. Cl. 250/231.1; 324/658; 324/207.11; 428/67

(57) ABSTRACT

A coding member having a plurality of base structures is illustrated. The base structures are arranged in a predetermined periodic manner and each base structure comprises first and second metal layers. The base structures are embedded in a body made from an encapsulant such that a surface of the first metal layer is exposed externally whereas the second metal layer is completely embedded inside the body. Encoders, having such coding member are illustrated. The encoders include transmissive and reflective optical encoders, as well as non-optical encoders such as magnetic and capacitive encoders.

### BACKGROUND

Encoders are sensing devices for sensing and measuring movements. In many automation systems, encoders are used for measuring absolute positions, or relative positions of components relative to predetermined reference points. Encoders used to determine absolute position are commonly known as absolute encoders whereas encoders used to determine relative positions are commonly known as incremental encoders. Generally, an encoder comprises a radiation source, a coding member, and a sensor. The radiation source may be a light source, a capacitive plate, or a magnet depending on the type of technology. There are three major types of encoders, i.e. the capacitive encoders, the magnetic encoders and optical encoders. Capacitive sensors work by sensing changes of capacitance; magnetic encoders work by sensing changes of magnetic field; whereas optical encoders work by sensing changes of light.

The encoders systems may be used in various applications. Some applications such as industrial automations require the encoders to operate in extreme conditions such as high temperature and high pressure. In some other consumer electronic applications such as printers, the operating condition may be less stringent. An encoder for consumer electronic applications may not have the required reliability performance to be used in industrial automations. The reliability of an encoder largely depends on the technology used in manufacturing the coding member.

Examples of the coding members commonly used today are glass code wheels, metal code wheels and polymer base code wheels. Coding patterns of a metal code wheel are fabricated through etching and characterized by the protrusions from the metal surface. A glass code wheel usually has a thin flat glass based body. The coding patterns, usually made from metal, are sputtered onto the glass surface. As a result, glass code wheels are characterized by the fact that the metal is usually protruding out from the thin flat glass. A polymer base code wheel usually has a polymer base body. An emulsion layer with photosensitive material is fully embedded inside the body. The photosensitive material usually defines the coding patterns. Unlike glass and metal-based code wheels, polymer base code wheels differ at least in that the emulsion layer is not exposed externally on any surface of the body.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements.

FIG. 1 illustrates a perspective view of a reflective encoder;

FIG. 2 illustrates code wheel used in an encoder;

FIG. 3 illustrates a cut away cross-sectional view of a coding member;

FIG. 4 illustrates an interlock aperture;

FIG. 5 illustrates how a coding member operates in a reflective encoder;

FIG. 6 illustrates how a coding member operates in a transmissive encoder; and

FIG. 7 illustrates how a coding member is fabricated.

### DETAILED DESCRIPTION

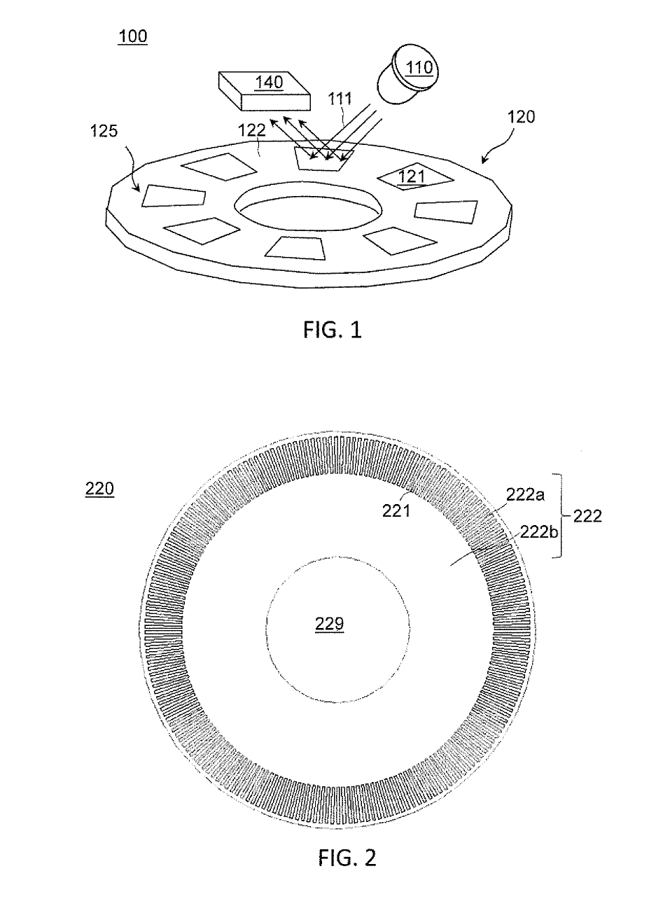

FIG. 1 illustrates a perspective view an encoder 100. The encoder 100 is generally used to sense and detect rotation of a moving disc. The encoder 100 comprises a radiation source 110, a coding member 120, and a sensor 140. The radiation source 110 generates electromagnetic radiation 111 such as light, and directs it towards the coding member 120. The encoder 100 may be an optical reflective encoder paired with the radiation source 110, which is a light source such as a light-emitting diode (referred herein after as LED). The coding member 120 comprises one region 125 for the purpose of selectively directing, redirecting or reflecting the radiation 111. In the embodiment shown in FIG. 1, the region 125 is a flat surface but in another embodiment, the region 125 may be a curved surface configured to focus the radiation 111. The coding member 120 has a plurality of base structures 121 arranged in accordance to a coding pattern on the region 125. The coding pattern may define a predetermined periodic pattern similar to those used in spatial filters. The coding member 120 is configured to direct the radiation 111 emitted from the radiation source 110 towards the sensor 140 in accordance to the coding pattern, modulating spatial information into the radiation 111 in the process.

As shown in the embodiment illustrated by FIG. 1, the base structures 121 are positioned in a row spaced out systematically at the periphery around the center of the coding member 120. The coding member 120 may be attached to a rotating object that rotates around a fixed axis, for example a rotating shaft of a motor system such that the center of the coding member 120 is on the fixed axis and the base structures 121 are configured to rotate around the fixed axis. The radiation source 110 is configured to emit the radiation 111 towards the coding member 120. The radiation 111 is reflected towards the sensor 140 by the base structures 121. However, as the coding member 120 rotates, the radiation 111 hits another portion 122 of the coding member 120 outside the base structures 121 where the radiation 111 is not reflected. At the portion 122 of the coding member 120, the radiation 111 may be absorbed, transmit through or being directed away from the sensor 140. This process repeats as the coding member 120 rotates further. In such a manner, the periodic pattern of the coding member 120 is modulated into the radiation 111, which is then detected by the sensor 140.

Coding members 120 used in rotational configuration are known as code wheels. In another embodiment, the plurality of base structures 121 may be arranged in linear form where the coding member 120 is movable in a back and forth manner in linear form rather than the rotational movement. Such coding members 120 involving linear movement are known as “code strips”. “Code wheels” and “code strips” are terminologies that are commonly used in the industry. However, the term “code wheels” and “code strips” may be narrowly interpreted to only a specific type of encoder. To avoid such confusion, the term “coding member” will be used hereinafter to include code wheels, code strips and any other similar structures of any geometry having such coding patterns for detecting movement. Unless specifically defined, all possible configurations should be taken into consideration although a specific type of coding member such as a “code wheel” or a “code strip” is discussed.

The plurality of base structures 121 may define any shape suitable to selectively direct or reflect radiation 111 to the sensor 140. In the embodiment shown in FIG. 1 each of the base structures 121 defines a substantially rectangular shape. In occasions where sinusoidal signal is preferred, the base structures 121 may define a diamond shape, an oval shape or a circular shape such that the signal detected at the sensor 140 is in a quasi sinusoidal waveform or a sinusoidal wave form.

For optical encoders, an optical lens (not shown) may be placed between the radiation source 110 and the coding member 120, between the coding member 120 and the sensor 140, or both. In some embodiment, a reticle may be placed between the coding member 120 and the sensor 140. Although a specific embodiment has been illustrated in FIG. 1, other arrangements and combinations of encoders may be implemented without departing from the teachings herein.

FIG. 2 illustrates a top view of coding member 220 for detecting rotary movement. The coding member 220 comprises a body 222 and a plurality of base structures 221. The plurality of base structures 221 are arranged in a predetermined periodic pattern. The body 222 is divided into two portions, e.g., a portion 222a adjacent to the plurality of base structures 221, and another portion 222b that is further distanced from the base structures 221. The coding member may comprise an optional hollow 229 at the center of the coding member 220. In the embodiment illustrated, the portion 222a is transparent whereas the portion 222b may be either transparent or opaque. Optionally, the portion 222a and 222b may be formed using different materials.

The coding member 220 may be a component used in for example, but not limited to, a reflective optical encoder, a transmissive optical encoder, a capacitive encoder, and a magnetic encoder. For reflective optical encoders, the base structures 221 may be reflective surfaces configured to reflective light. In the embodiment shown in FIG. 2, the body 222 may be configured to absorb light to reduce reflection. For transmissive optical encoders, the portion 222a may comprise a void or cavity to permit light to pass through. For magnetic encoders, the base structures 221 may be structures having magnetic poles adapted to create a magnetic field whereas the body 222 may be any material without magnetic properties. For capacitive encoders, the base structures 221 may be conductive plates configured to connect electrically to an external circuit, whereas the body 222 may be an electrically insulating material. For capacitive and magnetic encoders, the coding member 220 may further comprise a radiation source 110 (See FIG. 1).

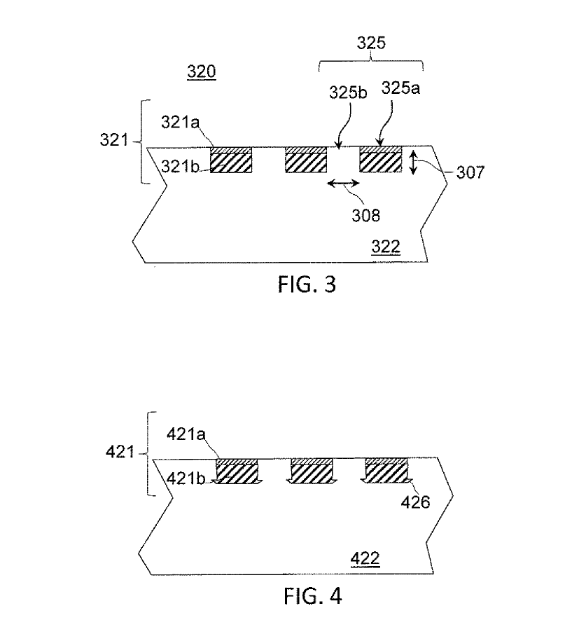

FIG. 3 illustrates an embodiment of a coding member 320 shown as a cutaway cross-sectional view. The coding member 320 comprises a plurality of base structures 321 and a body 322. The plurality of base structures 321 may be arranged in a predetermined periodic manner. The distance 308 between two adjacent base structures 321 determines the resolution of an encoder system. For example, in one embodiment illustrating a high resolution encoder, the distance 308 is less than 50 micro-meters.

Each of the plurality of base structures 321 comprises a first metal layer 321a and a second metal layer 321b. The plurality of base structures 321 are fully embedded inside the body 322 except that one side of the first metal layer 321a defining a surface 325a is exposed externally. The surface 325a may be flat or have a curvature such as for collimating radiation. The second metal layer 321b is encapsulated inside the body 322 such that the second metal layer 321b is surrounded by the body 322 and the first metal layer 321a. The coding member 320 has at least one region 325 configured to selectively direct radiation emitted from a radiation source 110 (See FIG. 1) to a sensor 140 (See FIG. 1). In the embodiment shown in FIG. 3, the region 325 is a surface defined by the surface 325a of the first metal layer 321a and a surface portion 325b of the body 322.

The coding member 320 illustrated in the embodiment shown in FIG. 3 differs from prior art metal code wheels and glass code wheels at least in that the plurality of base structures 321 are not protruded, but fully embedded inside the body 322 with the surface 325a exposed externally. The coding member 320 shown in FIG. 3 is without protrusions. Thus, light falling on the region 325 will not be dispersed. Similarly, in this embodiment the coding member 320 differs from conventional polymer code wheels at least in that the base structures 321 are not fully embedded, but having one surface 325a exposed externally. This prevents light falling on the region 325 from being refracted by any protection coating of the conventional polymer code wheels.

The first metal layer 321a is connected to the second metal layer 321b. The first metal layer 321a may be coated or formed on the second metal layer 321b. The first metal layer 321a may be made highly reflective for reflecting radiation from a radiation source. For example, when used in a reflective encoder 100 (See FIG. 1), the first metal layer 321a is configured to reflect radiation 111 emitted from the radiation source 110 (See FIG. 1). In the embodiment shown in FIG. 3, the first metal 321a is made from a metal that is resistant to corrosion. In another embodiment, the first metal layer 321a is a noble metal that is also resistant to oxidization such as gold. In yet another embodiment, the thickness of the first metal layer 321a may be less than 1 micro-meter.

The second metal layer 321b provides anchorage, and supports to the base structures 321 and the coding member 320. The second metal layer 321b may be made from copper, nickel or other metallic material suitable for anchorage purposes. Optionally, a layer of barrier metal (not shown) may be formed between the first metal layer 321a and the second metal layer 321b to prevent diffusion of the two metal layers 321a and 321b. Examples of barrier metals are palladium and nickel palladium. The second metal layer 321b may have a thickness 307 ranging between 5 and 100 micrometers.

The body 322 shown in the embodiment in FIG. 3 is made from an encapsulant, such as silicone, epoxy, a hybrid of silicone and epoxy, an amorphous polyamide resin or fluorocarbon, plastic, glass fillers, silica fillers, aluminum nitride filler, or combinations thereof. The body 322 may be transparent or opaque. However, for use in optical encoders, the body 322 is transparent to the radiation radiated from the radiation source 110 (See FIG. 1).

An interlock aperture 426 shown in FIG. 4 may be formed to improve reliability performance. Such interlock apertures 426 create mechanical interlocks between the body 422 and the base structures 421 to enhance the bonding of the body 422 and the base structures 421. The interlock structure 426 may be formed in at least one of the first metal layer 421a and the second metal layer 421b, or may be formed in both of the first 421a and second 421b metal layers.

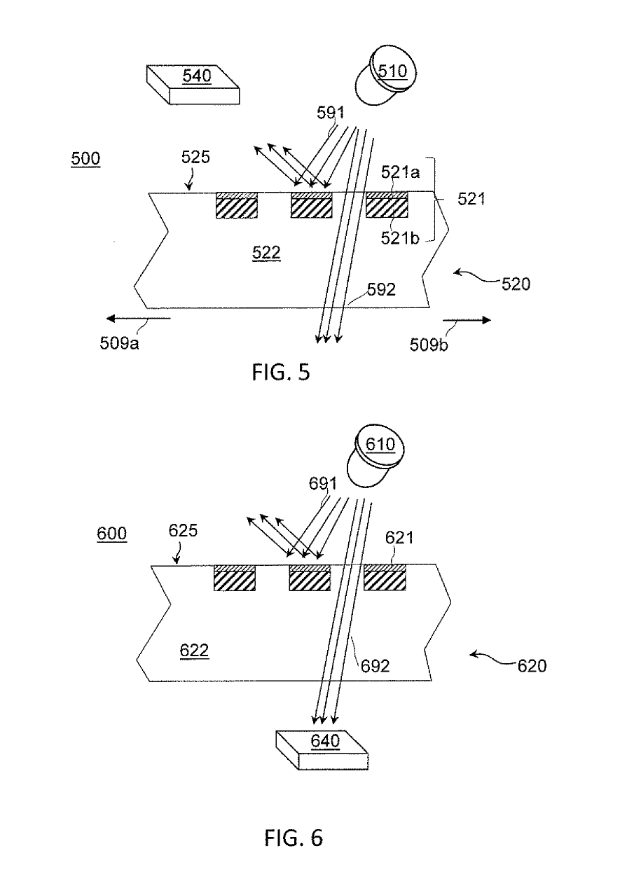

FIG. 5 and FIG. 6 illustrate how coding members 520 and 620 operate in reflective and transmissive configuration, respectively. The embodiment in FIG. 5 illustrates an encoder 500 comprising a radiation source 510, a coding member 520 and a sensor 540. The radiation source 510 and the sensor 540 are located on the same side facing a region 525 adapted to receive radiation 591 and 592 emitted from the radiation source 510. The region 525 may be a flat surface or alternatively other geometry suitable to direct or redirect radiation 591 and 592. The coding member 520 has a body 522, and a plurality of base structures 521 comprising first 521a and second 521b metal layers. In one embodiment, the sensor 540 may comprise a plurality of sensing units such as photodiodes arranged in accordance to the plurality of base structures 521.

A portion 591 of the radiation emitted from the radiation source 510 is directed or reflected towards the sensor 540 by the base structures 521. However, another portion 592 of the radiation transmits through the body 522 and being directed away from the sensor 540 as the body 522 in the embodiment of FIG. 5 is transparent to the radiation 592. In another embodiment, the body 522 may be configored to absorb the radiation 592. Alternatively in yet another embodiment, the body 522 may reflect the radiation 592 away from the sensor 540. As the coding member 520 moves along any direction 509a or 509b, the sensor 540 detects the reflected radiation 592 and not the radiation 591. The radiation 591 and 592 may be detected using different portions (not shown) of the sensor 540. As the coding member 520 moves further, the radiation 591 is detected. The radiations 591 and 592 are detected alternately in a predetermined periodic manner. The signal detected at the sensor 540 is then processed to detect movements or to compute the speed of the movement.

For encoders 600 in transmissive configuration as shown in FIG. 6, the sensor 640 and the radiation source 610 are located on different sides of the coding member 620. In the embodiment shown in FIG. 6, the radiation source 610 is located facing a region 625 adapted to receive radiation 691 and 692 emitted from the radiation source 610. A portion 691 of the radiation is reflected or directed away from the sensor 640 by the plurality of base structures 621 but another portion 692 of the radiation 692 is transmitted through the body 622 towards the sensor 640. As the coding member 620 moves, the radiation 691 is detected and the radiation 692 is directed away from the sensor 640. This repeats as the coding member 620 moves further and the detected signals can be used to detect movement or speed.

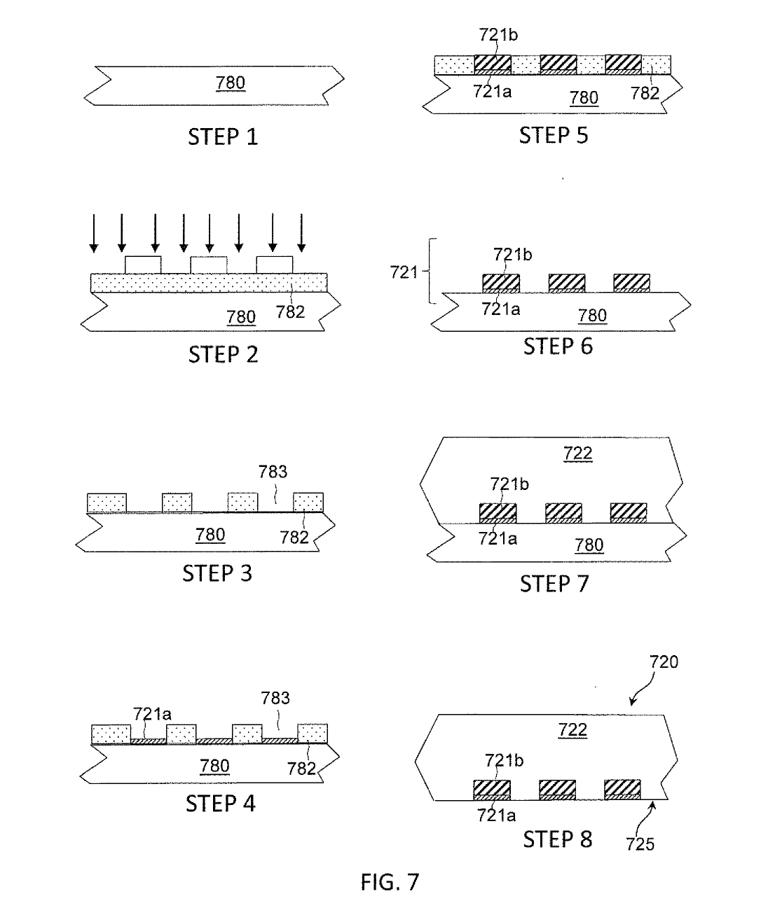

FIG. 7 illustrates how a coding member 720 is fabricated. The process starts with a base metal 780 shown in STEP 1. The base metal 780 may be a part of a fabrication jig that is removed at the end of the fabrication process. The base metal 780 may be compatible with material used to form the base structures 721 such that the base structures 721 can be formed on and adhered to the base metal 780. Next, as shown in STEP 2, the base metal 780 is coated with a photoresist material 782. The photoresist material 782 is then exposed to light illuminated in a predetermined pattern using photographic technique. In STEP 3, a portion of the photoresist material 782 that was blocked from light is then removed, leaving behind a portion of photoresist material 782 that was exposed to light. At this stage, the photoresist material 782 defines a plurality of apertures 783.

The process then proceeds to STEP 4 in which a layer of first metal layer 721a is added to the apertures 783 by going through a plating process. The plating process can be either typical electro deposition process, or electro-less deposition process, such as immersion gold plating process. Subsequently in the following STEP 5, the second metal layer 721b is added onto the first metal layer 721a to achieve the desired overall metal thickness. To be cost effective, the first metal layer 721a may be gold but the second metal layer 721b may be other cheaper material such as copper and nickel. The second metal layer 721b may be formed thicker than the photoresist material 782 so that the second metal layer 721 overflows the cavities 78 forming mushroom shape interlocking structures 426 shown in FIG. 4.

In STEP 6, the photoresist material 782 is removed, leaving behind a plurality of base structures 721 defined by the first 721a and second 721b metal layers. The plurality of base structures 721 are then encapsulated by an encapsulant as shown in STEP 7. The encapsulant forms the body 722, which may be in liquid or semiliquid form in the beginning, but cured into solid form at the end of the process. The body 722 may be formed using transfer molding, casting, injection molding, or other similar process. The body 722 may comprise epoxy, silicone, a hybrid of silicone and epoxy, an amorphous polyamide resin or fluorocarbon, plastic, glass fillers, silica fillers, aluminum nitride filler, or combinations thereof. For example, the encapsulant may be NT-330HQ from Nitto Denko, or opaque material, for example, NT-8570 of Nitto Denko, or EME-E670 of Sumitomo Bakelite.

In STEP 8, the base metal 780 is removed, for example by being etched away using chemical solution. During this process, the first metal layer 721a will act as etch-resist layer. The metal etching process produces a region 725 which defines a surface for directing or redirecting radiation, and yields the entire coding member 720.

Although specific embodiments of the invention have been described and illustrated, the invention is not to be limited to the specific forms or arrangements of parts so described and illustrated. For example, a radiation source may be a light-emitting diode configured to emit light, but also other radiation source configured to emit electromagnetic wave in different wavelength invisible to human eyes. The radiation source and other elements described may be other later developed component without departing from the spirit of the invention. It is to be understood that the illustration and description shall not be interpreted narrowly. The scope of the invention is to be defined by the claims appended hereto and their equivalents.

What is claimed is:

1. A coding member, comprising:
a plurality of base structures; and
a body encapsulating the plurality of base structures;
wherein each base structure comprises a first metal layer and a second metal layer being connected to each other;
wherein the first metal layer is embedded inside the body having a surface exposed externally;
wherein the second metal layer is embedded inside the body such that the second metal is surrounded by the body and the first metal layer; and
wherein the plurality of base structures are arranged in a predetermined periodic manner for modulating radiation emitted from a radiation source to a sensor.

2. The coding member of claim 1, wherein the body and the surface of the first metal layer define a region configured to direct the radiation emitted from the radiation source to the sensor in accordance to the predetermined periodic manner.

3. The coding member of claim 1, wherein the first metal layer comprises a metal that is resistant to corrosion.

4. The coding member of claim 1, wherein the body has a portion transparent to a previously selected radiation source.

5. The coding member of claim 1, wherein the second metal layer comprises copper.

6. The coding member of claim 1, wherein the second metal layer comprises nickel.

7. The coding member of claim 1, wherein each of the plurality of base structures is spaced less than 50 micrometers from another adjacent base structure.

8. The coding member of claim 1, wherein the second metal layer has a thickness between 5 micrometers and 100 micrometers.

9. The coding member of claim 1, wherein each base structure further comprises an interlock structure to provide mechanical interlock between the body and the base structure.

10. The coding member of claim 1, wherein the body comprises silicone.

11. The coding member of claim 1, wherein the coding member, the radiation source and the sensor forms a portion of a capacitive encoder.

12. The coding member of claim 1, wherein the coding member, the radiation source and the sensor form a portion of a magnetic encoder.

13. An optical encoder, comprising:
a light source configured to generate light;
a sensor; and
a coding member for selectively directing light from the light source to the sensor;
wherein the coding member comprises a plurality of base structures and a body;
wherein each of the base structures comprises first and second metal layers connected to each other;
wherein the first and second metal layers are embedded in the body such that the first metal layer is exposed externally on one side and the second metal layer is surrounded by the body and the first metal layer; and
wherein the plurality of based structures are arranged in a predetermined periodic manner for modulating light emitted from the light source to the sensor.

14. The optical encoder of claim 13, wherein the one side of the first metal layer and the body define a region configured to direct the radiation emitted from the radiation source to the sensor in accordance to the predetermined periodic manner.

15. The optical encoder of claim 13, wherein the first metal layer comprises a metal resistant to corrosion.

16. The optical encoder of claim 13, wherein the body has a transparent portion.

17. The optical encoder of claim 13, wherein each of the plurality of base structures is spaced less than 50 micrometers apart from an adjacent base structure.

18. The optical encoder of claim 13, wherein the second metal layer has a thickness between 5 micrometers and 100 micrometers.

19. The optical encoder of claim 13, wherein the base structure further comprises an interlock structure to provide mechanical interlock between the body and the base structure.

20. An encoder system, comprising:
a radiation source, the radiation source being configured to emit a radiation;
a coding member for modulating the radiation;
a sensor for detecting the radiation modulated by the coding member; and
a controller electrically connected to the sensor;
wherein the coding member comprises a plurality of base structures and a body encapsulating the plurality of base structures;
wherein each base structure comprises a first metal layer and a second metal layer being connected to each other;
wherein the first and second metal layers are embedded inside the body such that the first metal layer having a surface exposed externally, and the second metal is surrounded by the body and the first metal layer; and
wherein the plurality of base structures are arranged in a predetermined periodic manner for modulating the radiation emitted from the radiation source.
